(19) United States
(12) Patent Application Publication
(10) Pub. No.: US 2008/0116572 A1
(43) Pub. Date: May 22, 2008

(54) Semiconductor memory modules, methods of arranging terminals therein, and methods of using thereof

(75) Inventors: Seung-duk Baek, Hwaseong-si (KR); Sun-won Kang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/980,347

(22) Filed: Oct. 31, 2007

(30) Foreign Application Priority Data
Nov. 21, 2006 (KR) 10-2006-0115421

(51) Int. Cl. H05K 7/00; H01L 23/52

(52) U.S. Cl. 257/734; 361/728; 257/E23.141

(57) ABSTRACT

Example embodiments may provide a semiconductor memory module having shorter length of terminal stubs, a method of arranging terminals to reduce or minimize length of each stub, and methods of using the same. Example embodiment semiconductor memory modules may include first and second semiconductor memory devices each having terminals in an edge region close to a corresponding semiconductor memory device such that terminals of the first and second semiconductor memory devices may be arranged symmetrically to each other.

### PRIORITY STATEMENT

This application claims benefit under § 119 to Korean Patent Application No. 10-2006-0115421, filed on Nov. 21, 2006, in the Korean Intellectual Property Office, the entire disclosure of which is incorporated herein by reference.

### BACKGROUND

1. Field

Example embodiments may relate to a semiconductor memory module and/or methods of arranging terminals in semiconductor memory modules, for example, to an example method of reducing or minimizing a length of each stub in a semiconductor memory module.

2. Description of the Related Art

In order to remain compatible with increased speed and performance of central processing units (CPUs), semiconductor memory devices may have higher speed and/or density. Additionally, related art semiconductor memory modules, in which a plurality of semiconductor memory devices may be mounted in one or more rows, may themselves have higher speed and/or density.

FIG. 1A is a diagram of a related art semiconductor memory module 100, in which a plurality of semiconductor memory devices may be mounted in two rows.

FIG. 1A illustrates the related art semiconductor memory module 100 that may include a plurality of semiconductor memory devices A1 through A8 in a first row, a plurality of semiconductor memory devices B1 through B8 in a second row, a plurality of module tabs 102, and/or a module board 104. The semiconductor memory devices A1 through A8 and B1 through B8 may be mounted in two or more rows, or they may be mounted on both front and back surfaces of a module board 104. Each of the semiconductor memory devices A1 through A8 and B1 through B8 may receive signals from an external memory controller through corresponding module tabs 102.

FIG. 1B is a detailed diagram of the related art memory block 110 of FIG. 1A.

FIG. 1B illustrates a module tab TAB and/or a memory controller 120 connected to the memory block 110, which may include a plurality of semiconductor memory devices A1, B1, A2, and B2, a plurality of traces 10, 21, and 22, and/or a plurality of stubs 31, 32, 33, and 34.

Traces may be signal lines on the module board 104 of FIG. 1A. Terminal traces directly connected to semiconductor memory devices may be conventionally referred to as stubs. Trace 21 may be shared by the semiconductor memory devices A1 and/or B1. Trace 22 may be shared by the semiconductor memory devices A2 and/or B2. Trace 10 may be shared by the first, second, third, and/or fourth semiconductor memory devices A1, B1, A2 and B2.

FIG. 2 is a detailed diagram of the related art memory block 110 of FIG. 1B.

FIG. 2 illustrates the related art memory block 110 including the plurality of semiconductor memory devices A1, B1, A2 and B2, each of which may include a plurality of terminals CA1, CA2, CA3 and CA4 and/or DQ1, DQ2, DQ3 and DQ4, the plurality of traces 10, 21 and 22, and/or the plurality of stubs 31, 32, 33 and 34.

Terminals DQ1, DQ2, DQ3 and DQ4 may receive and/or output data signals individually for each semiconductor memory device, and terminals CA1, CA2, CA3 and CA4 may receive command signals and/or address signals commonly.

Terminals CA1 of the semiconductor memory devices A1, B1, A2, and B2 may commonly receive command signals and/or address signals. Terminals CA2 of the semiconductor memory devices A1, B1, A2, and B2 may also commonly receive command signals and/or address signals (connection not shown). This kind of multi-drop method may also be applied to terminals CA3 and/or CA4.

To operate a semiconductor memory module at high speed, capacitance of each semiconductor memory device in a related art semiconductor memory module may need to be reduced. Lengths of stubs directly connected to each of the semiconductor memory devices may need to be shortened. Long stub lengths may cause a larger amount of parasitic capacitance and/or stray capacitance.

### SUMMARY

Example embodiments may provide a semiconductor memory module having reduced or minimized stub lengths and/or methods of arranging terminals to reduce or minimize stub length in semiconductor memory modules.

Example embodiments may provide a semiconductor memory module including first and second semiconductor memory devices having some terminals at in edge region of the first semiconductor memory device close to the second semiconductor memory device. Some terminals of the second semiconductor memory device may be in an edge region of the second semiconductor memory device close to the first semiconductor memory device. Some terminals of the first semiconductor memory device and the second semiconductor memory device may be arranged symmetrically to each other.

A terminal of the first semiconductor memory device (“first terminal”), and a terminal of the second semiconductor memory device (“second terminal”) arranged symmetrically to the first terminal may be connected to each other using a multi-drop method.

The first and second terminals may be common terminals which receive signals from a same trace.

The signals, which may be received by common terminals from the same trace, may be command signals and/or address signals.

Terminals of the first and second semiconductor memory devices may be bonding pads, solder ball pads, redistribution line (RDL) pads, flip-chip bumping pads, and/or any other suitable type of pad

If terminals of the first and second semiconductor memory devices are arranged symmetrically to each other to form a pair of semiconductor memory devices having first and second forms, terminals of the first semiconductor memory device may have the first form and terminals of the second semiconductor memory device may have the second form. Alternatively, terminals of the first and second semiconductor memory devices may initially share a basic form, and then terminals of the first semiconductor memory device may be transformed to have the first form and terminals of the second semiconductor memory device may be transformed to have the second form by a switching option and/or fuse cutting.

The first and second semiconductor memory devices may be chips, RDL chips, packages, wafer level packages, and/or another suitable memory device form.

The first and second semiconductor memory devices may be mono devices and/or stacked devices having mono devices stacked on one another.

Example embodiment semiconductor memory modules may include two or more rows of semiconductor memory devices.

Example methods may include arranging terminals in a semiconductor memory module having first, second, third, and/or fourth semiconductor memory devices, arranging terminals of the first semiconductor memory device in an edge region of the first semiconductor memory device close to the second semiconductor memory device, and arranging terminals of the second semiconductor memory device in an edge region of the second semiconductor memory device close to the first semiconductor memory device. Terminals of the first and second semiconductor memory devices may be arranged symmetrically to each other. Example methods may further include arranging terminals of the third semiconductor memory device in an edge region of the third semiconductor memory device close to the fourth semiconductor memory device and arranging terminals of the fourth semiconductor memory device in an edge region of the fourth semiconductor memory device close to the third semiconductor memory device. Terminals of the third and fourth semiconductor memory devices may be arranged symmetrically to each other.

If each of the first, second, third and fourth semiconductor memory devices include terminals 1 through N, a terminal n (n being any number selected from 1 to N) of the first semiconductor memory device, a terminal n of the second semiconductor memory device, a terminal n of the third semiconductor memory device, and/or a terminal n of the fourth semiconductor memory device may be common terminals that may receive signals from a common trace.

Terminal n of the first semiconductor memory device may receive signals from an external memory controller through a first stub, a common trace, and/or a common module tab; terminal n of the second semiconductor memory device may receive signals from the external memory controller through a second stub, the common trace, and/or the common module tab; terminal n of the third semiconductor memory device may receive signals from the external memory controller through a third stub, the common trace, and/or the common module tab; and/or terminal n of the fourth semiconductor memory device may receive signals from the external memory controller through a fourth stub, the common trace, and/or the common module tab.

Length of the first, second, third and/or fourth stubs may be reduced or minimized by symmetrically arranging terminals n of the first and second semiconductor memory devices in edge regions close to each other and/or by symmetrically arranging terminals n of the third and fourth semiconductor memory devices in edge regions close to each other.

### BRIEF DESCRIPTION OF THE DRAWINGS

The above and/or other features and advantages of example embodiments will become more apparent by describing them in detail with reference to the attached drawings in which:

FIG. 1A is a diagram of a related art semiconductor memory module in which a plurality of semiconductor memory devices may be mounted in two rows;

FIG. 1B is a diagram of the related art memory block of FIG. 1A in detail;

FIG. 2 is a diagram of the related art memory block of FIG. 1B in greater detail;

FIG. 3 is a diagram illustrating terminal arrangement of an example embodiment semiconductor memory module; and

FIGS. 4A and 4B illustrate further example embodiments of a semiconductor memory module.

### DETAILED DESCRIPTION

Example embodiments will now be described more fully with reference to the accompanying drawings. Embodiments, however, may be embodied in many different forms and should not be construed as being limited to example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

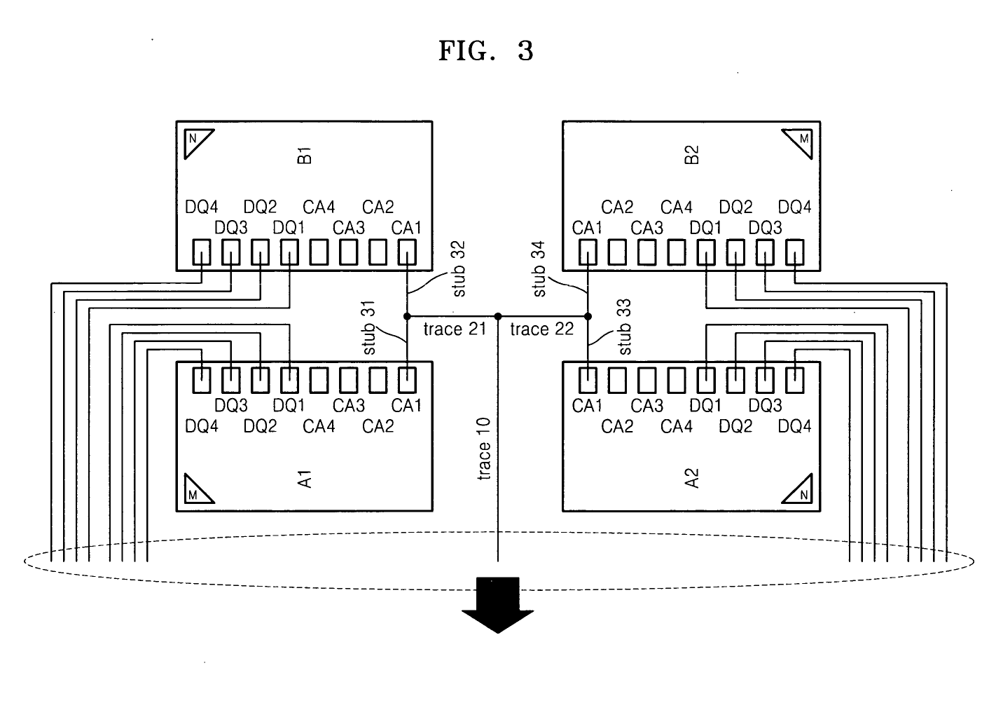

Reference will now be made to example embodiments, which are illustrated in the accompanying drawings, wherein like reference numerals may refer to like components throughout. FIG. 3 is a diagram illustrating terminal arrangement of an example embodiment semiconductor memory module.

FIG. 3 illustrates a plurality of traces 10, 21, and 22, a plurality of stubs 31, 32, 33, and 34, and/or a plurality of semiconductor memory devices A1, B1, A2, and B2, each of which may include a plurality of terminals CA1, CA2, CA3, and CA4 and/or DQ1, DQ2, DQ3 and DQ4, which may be a subset of all terminals of the semiconductor memory devices.

The example embodiment semiconductor memory module of FIG. 3 may include two rows of semiconductor memory devices including first semiconductor memory devices A1 and A2 in a first row and second semiconductor memory devices B1 and B2 in a second row. Example embodiment semiconductor memory modules may include two or more rows of semiconductor memory devices A1, B1, A2 and B2. Semiconductor memory devices may have higher density by including two or more rows of semiconductor memory devices.

As shown in FIG. 3, terminals CA1, CA2, CA3, and/or CA4 may be arranged in edge regions of the first, second, third, and/or fourth semiconductor memory devices A1, B1, A2, and B2 in the example embodiment semiconductor memory module. Terminals CA1, CA2, CA3, and/or CA4 in a first semiconductor memory device A1 may be in an edge region close to a second semiconductor memory device B1. The edge regions may be any region or combination of regions on A1 close to B1, for example, top, bottom, left, and/or right edge regions of the first semiconductor memory device A1. Terminals CA1, CA2, CA3, and/or CA4 of the second semiconductor memory device B1 may be arranged in an edge region close to the first semiconductor memory device A1. The edge regions may be any region or combination of regions on B1 close to A1, for example, top, bottom, left, and/or right edge regions of the second semiconductor memory device B1 and may mirror the edge region of A1. Terminals CA1, CA2, CA3, and/or CA4 of the first semiconductor memory device A1 and terminals CA1, CA2, CA3, and/or CA4 of the second semiconductor memory device B1 may be arranged symmetrically; for example, terminals CA1 of the first and second semiconductor memory devices A1 and B1 may correspond to each other, terminals CA2 of the first and second semiconductor memory devices A1 and B1 may correspond to each other, and so on.

As shown in FIG. 3, terminals CA1, CA2, CA3, and/or CA4 of third semiconductor memory device A2 and a fourth semiconductor memory device B2 may be symmetrically arranged in edge regions of the respective semiconductor memory devices which are close to the corresponding semiconductor memory device. Terminals DQ1, DQ2, DQ3, and/or DQ4 of the first and second semiconductor memory devices A1 and B1 may also be symmetrically arranged in edge regions of the respective semiconductor memory devices, as may be terminals DQ1, DQ2, DQ3, and/or DQ4 of the third and fourth semiconductor memory devices A2 and B2, as shown in FIG. 3.

Terminals CA1 of the semiconductor memory devices A1, B1, A2, and B2 may be connected to each other using, for example, a multi-drop method. Terminals CA1 of the first and second semiconductor memory devices A1 and B1 may receive signals from a common trace 21, and terminals CA1 of the third and fourth semiconductor memory devices A2 and B2 may receive signals from a common trace 22. Terminals CA1 of the semiconductor memory devices A1, B1, A2, and B2 may be common terminals that receive signals from a trace 10. Example multi-drop methods may similarly be applied to terminals CA2, CA3, and/or CA4. Terminals DQ1, DQ2, DQ3, and/or DQ4 that may receive and/or transmit data signals individually for their respective semiconductor memory device may not share common terminals.

Terminals related to power/ground signals and/or clock signals are not shown in FIG. 3. Terminals DQ1, DQ2, DQ3, and/or DQ4 may relate to data signals, and terminals CA1, CA2, CA3, and/or CA4 may relate to command signals and/or address signals. These relations are exemplary; any signals may be used with terminals based on the application of the terminals.

As shown in FIG. 3, terminals DQ1, DQ2, DQ3, and/or DQ4 may receive and/or output data signals individually for their respective semiconductor memory devices, and common terminals of CA1, CA2, CA3, and/or CA4 may receive command signals and/or address signals. The common terminals may receive signals input using an example multi-drop method from a common trace.

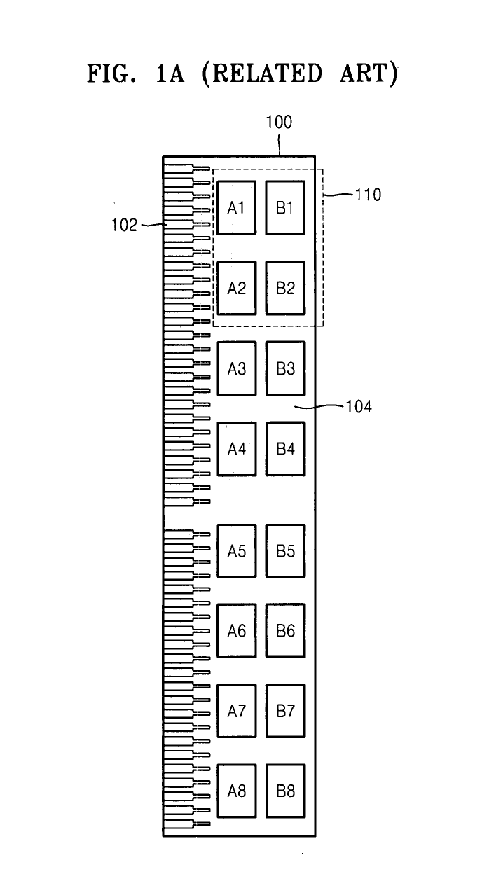

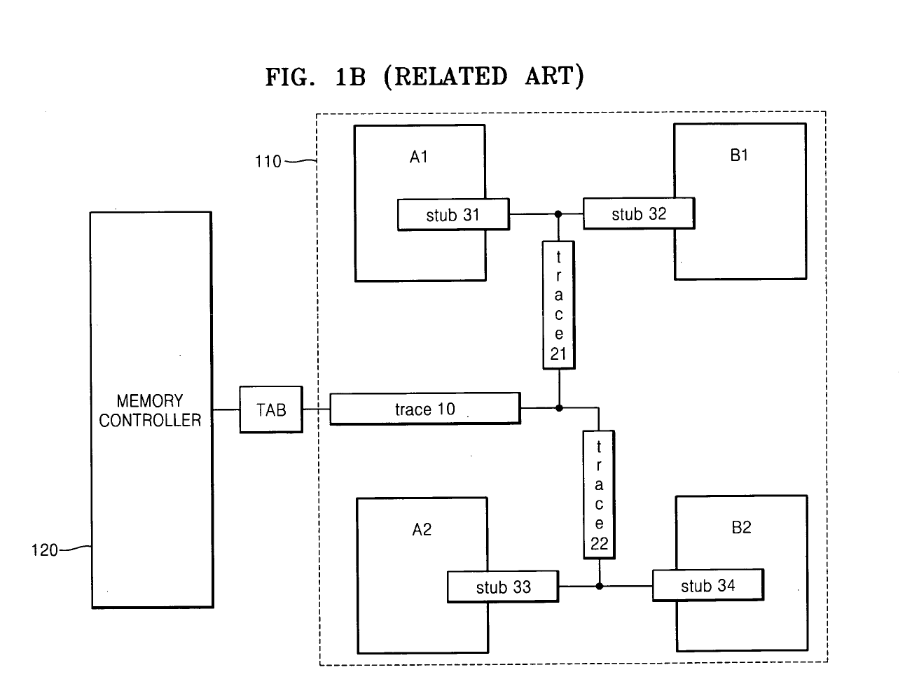

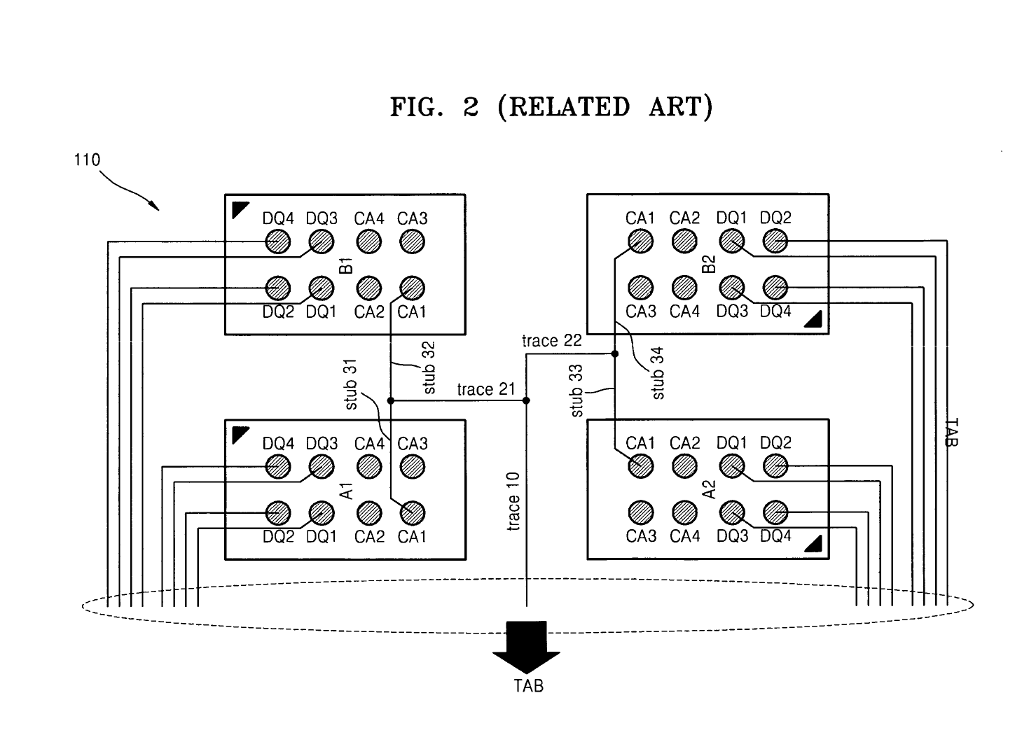

Terminal CA1 of the first semiconductor memory device A1 may receive signals from an external memory controller (for example, the related art memory controller 120 of FIG. 1B) through stub 31, the common traces 21 and 10, and/or the common module tab TAB. Terminal CA1 of the second semiconductor memory device B1 may receive signals from an external memory controller through stub 32, the common traces 21 and 10, and/or the common module tab TAB. Length of stubs 31 and 32 may be reduced or minimized by symmetrically arranging terminals CA1 of the first and second semiconductor memory devices A1 and B1 in edge regions of their respective semiconductor memory devices close to the other semiconductor memory device's edge region.

Terminal CA1 of the third semiconductor memory device A2 may receive signals from an external memory controller through stub 33, the common traces 22 and 10, and/or the common module tab TAB. Terminal CA1 of the fourth semiconductor memory device B2 may receive signals from an external memory controller through stub 34, the common traces 22 and 10, and/or the common module tab TAB. Length of stubs 33 and 34 may be reduced or minimized by symmetrically arranging terminals CA1 of the third and fourth semiconductor memory devices A2 and B2 in edge regions of their respective semiconductor memory devices close to the other semiconductor memory device's edge region.

Example embodiment semiconductor memory modules may reduce or minimize length of each stub by symmetrically arranging the common-related terminals in edge regions of their respective semiconductor memory devices close to an adjacent semiconductor memory device. Example embodiment semiconductor memory modules may be operated at higher speed by reducing length of each stub.

As shown in FIG. 3, terminals CA1, CA2, CA3, and/or CA4 of the semiconductor memory devices A1, B1, A2, and B2 may be embodied by bonding pads, solder ball pads, redistribution line (RDL) pads, flip-chip bumping pads, and/or any other type of suitable terminal structure. Example embodiments may include variety and combination of types of interconnection terminals.

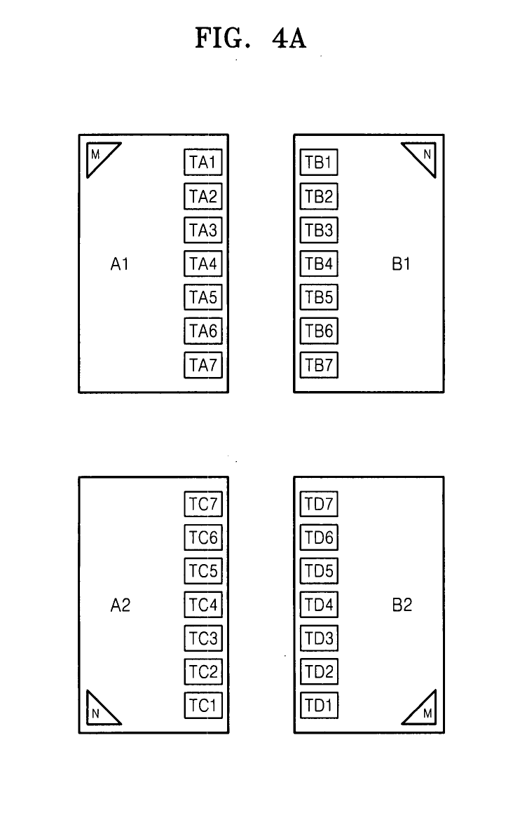

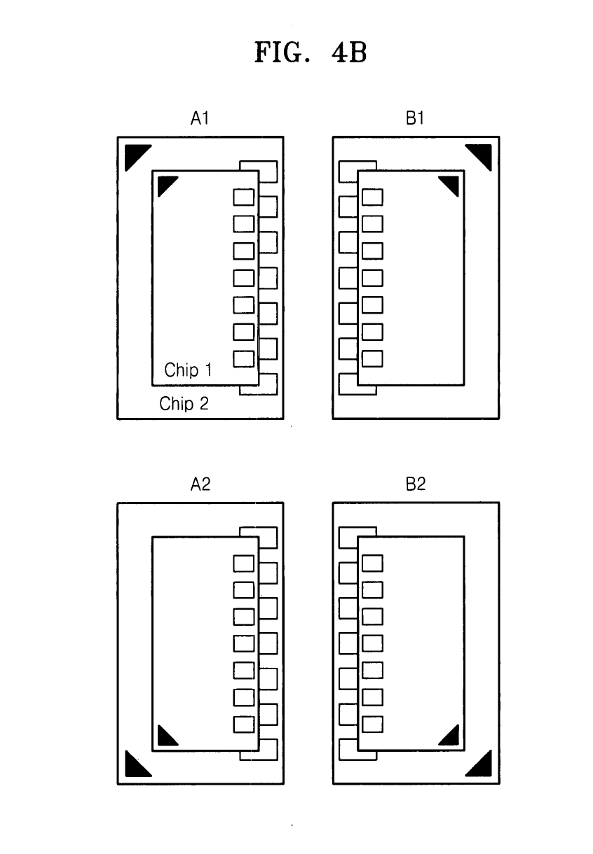

As shown in FIG. 3, the first semiconductor memory device A1 and/or the fourth semiconductor memory device B2 may be M-type, and the second semiconductor memory device B1 and/or the third semiconductor memory device A2 may be N-type. M-type and N-type will be described with reference to FIG. 4A.

FIGS. 4A and 4B illustrate example embodiment semiconductor memory modules.

As shown in FIG. 4A, terminals TA1 through TA7 of a first semiconductor memory device A1 may be symmetric with terminals TB1 through TB7 of a second semiconductor memory device B1. Terminals TC1 through TC7 of a third semiconductor memory device A2 may be symmetric with terminals TD1 through TD7 of a second semiconductor memory device B2. If a first form (for example, M-type) semiconductor memory device and a second form (for example, N-type) semiconductor memory device are paired symmetrically, terminals TA1 through TA7 of the first semiconductor memory device A1 may have the first form (M-type) and terminals TB1 through TB7 of the second semiconductor memory device B1 may have the second form (N-type). Terminals TC1 through TC7 of the third semiconductor memory device A2 may have the second form (N-type) and terminals TD1 through TD7 of the fourth semiconductor memory device B2 may have first form (M-type).

To arrange terminals to be symmetric, terminals of one of the pair of the semiconductor memory devices may need to be of the first form and terminals of the other of the pair of the semiconductor memory devices may need to be of the second form. Example methods of manufacturing semiconductor memory devices to form a semiconductor memory module having a symmetrical form may be described below.

In an example method, M-type semiconductor memory devices and/or N-type semiconductor memory devices may be manufactured using independent methods. For example, in semiconductor memory devices like the example embodiments shown in FIG. 4A, terminals TA1 through TA7 of the first semiconductor memory device A1, and/or terminals TD1 through TD7 of the fourth semiconductor memory device B2 may be initially formed to be of the first form. Terminals TB1 through TB7 of the second semiconductor memory device B1 and/or terminals TC1 through TC7 of the third semiconductor memory device A2 may be initially formed to be of the second form.

Alternatively, all the semiconductor memory devices may be initially formed to be a common basic form, and then some semiconductor memory devices may be transformed to be of the M-type and remaining semiconductor memory devices may be transformed to be of the N-type by, for example, secondary switching option and/or fuse cutting. In an example method, the semiconductor memory devices shown in FIG. 4A may all be primarily manufactured in a shared basic form, and terminals TA1 through TA7 of the first semiconductor memory device A1 and terminals TD1 through TD7 of the fourth semiconductor memory device B2 may later be transformed to be of the first form (M-type), and/or terminals TB1 through TB7 of the second semiconductor memory device B1 and terminals TC1 through TC7 of the third semiconductor memory device A2 may later be transformed to be of the second form (N-type) by, for example, secondary switching option, fuse cutting, and/or any other suitable transformation method.

First, second, third, and fourth example embodiment semiconductor memory devices A1, B1, A2 and B2 of FIGS. 3 and 4A may be embodied by chips, RDL chips, packages, wafer level packages, and/or any other suitable semiconductor memory device type. The first, second, third, and/or fourth example embodiment semiconductor memory devices A1, B1, A2, and B2 of FIGS. 3 and 4A may be mono devices and/or stacked devices including stacked mono devices. For example, in an example embodiment semiconductor memory module shown in FIG. 4B, stacked devices A1, B1, A2, and B2 in which mono devices CHIP1 and CHIP2 may be stacked on one another are illustrated. Example embodiments may include semiconductor memory modules having a variety of semiconductor memory devices stacked or otherwise arranged in a variety of ways.

Example methods may include arranging terminals in a semiconductor memory module including first, second, third, and/or fourth semiconductor memory devices A1, B1, A2, and B2. Example methods of arranging terminals are described in detail with reference to the example embodiment in FIG. 3.

Terminals CA1, CA2, CA3, and CA4 of a first semiconductor memory device A1 may be arranged in an edge region close to a second semiconductor memory device B1, and terminals CA1, CA2, CA3, and CA4 of the second semiconductor memory device B1 may be arranged in an edge region close to the first semiconductor memory device A1. Terminals CA1, CA2, CA3 and CA4 of the first semiconductor memory device A1 and terminals CA1, CA2, CA3 and CA4 of the second semiconductor memory device B1 may be arranged symmetrically to each other.

Terminals CA1, CA2, CA3, and CA4 of a third semiconductor memory device A2 may be arranged in an edge region close to a fourth semiconductor memory device B2, and terminals CA1, CA2, CA3, and CA4 of the fourth semiconductor memory device B2 may be arranged in an edge region close to the third semiconductor memory device A2. Terminals CA1, CA2, CA3, and CA4 of the third semiconductor memory device A2 and terminals CA1, CA2, CA3, and CA4 of the fourth semiconductor memory device B2 may be arranged symmetrically to each other.

As shown in FIG. 3, if each of the first, second, third, and fourth semiconductor memory devices A1, B1, A2, and B2 include terminals 1 through N, terminals n (for example, terminals CA1) of the first, second, third, and fourth semiconductor memory devices A1, B1, A2, and B2 may be common terminals that may receive command signals and/or address signals from a common trace 10. Here, n may be any natural number selected from 1 to N.

Terminal n (for example, terminal CA1) of the first semiconductor memory device A1 may receive signals from an external memory controller (for example, the related art memory controller 120 of FIG. 1B) through a first stub (for example, stub 31), common traces 21 and 10, and/or a common module tab TAB. Terminal n (for example, terminal CA1) of the second semiconductor memory device B1 may receive signals from an external memory controller through a second stub (for example, stub 32), common traces 21 and 10, and/or a common module tab TAB. Terminal n (for example, terminal CA1) of the third semiconductor memory device A2 may receive signals from an external memory controller through a third stub (for example, stub 33), a common trace 22, the common trace 10, and/or a common module tab TAB. Terminal n (for example, terminal CA1) of the fourth semiconductor memory device B2 may receive signals from an external memory controller through a fourth stub (for example, stub 34), common traces 22 and 10, and/or a common module tab TAB.

Terminal n (for example, terminal CA1) of the first semiconductor memory device A1 and terminal n (for example, terminal CA1) of the second semiconductor memory device B1 may be symmetrically arranged in edge regions of their respective semiconductor memory devices close to the other semiconductor device, and terminal n (for example, terminal CA1) of the third semiconductor memory device A2 and terminal n (for example, terminal CA1) of the fourth semiconductor memory device B2 may be symmetrically arranged in their respective semiconductor memory devices close to the other semiconductor device. Length of a first stub (for example, stub 31), second stub (for example, stub 32), third stub (for example, stub 33) and/or fourth stub (for example, stub 34) may be reduced or minimized.

Stub length in example embodiment semiconductor memory modules may be reduced or minimized by symmetrically arranging common terminals in edge regions of their respective semiconductor memory devices close to corresponding semiconductor devices. Example embodiment semiconductor memory modules may be operated at higher speed.

While example embodiments have been particularly shown and described with reference to the attached drawings, it will be understood by those skilled in the art that various changes in form and details may be made therein without departing from the spirit and scope of the disclosure as defined by the appended claims. The exemplary embodiments should be considered in descriptive sense only and not for purposes of limitation. Therefore, the scope of the disclosure is defined not by the detailed description but by the appended claims, and all differences within the scope will be construed as being included in the present application.

What is claimed is:

1. A semiconductor memory module comprising:
at least one first semiconductor memory device including at least one first terminal in a first edge region; and
at least one second semiconductor memory device including at least one second terminal in a second edge region, wherein the first edge region corresponds to an edge region of the at least one first semiconductor memory device nearest to the at least one second semiconductor memory device, wherein the second edge region corresponds to an edge region of the at least one second semiconductor device nearest to the first semiconductor memory device, and wherein the at least one first terminal and the at least one second terminal are arranged symmetrically.

2. The semiconductor memory module of claim 1, wherein the at least one first terminal and the at least one second terminal are connected to each other by a multi-drop method.

3. The semiconductor memory module of claim 2, wherein the at least one first terminal and the at least one second terminal share at least one trace.

4. The semiconductor memory module of claim 3, wherein the at least one first terminal and the at least one second terminal are configured to receive command signals and address signals transmitted through the at least one trace.

5. The semiconductor memory module of claim 1, wherein the at least one first terminal receives command signals and address signals from the external memory controller through a first stub, at least one common trace and a common module tab, and wherein the at least one second terminal receives the command signals and the address signals through a second stub, the at least one common trace and the common module tab.

6. The semiconductor memory module of claim 5, wherein the lengths of the first stub and the second stub are minimized by symmetrically arranging the first terminal and the second terminal at the edge regions close to each other.

7. The semiconductor memory module of claim 1, wherein the at least one first terminal and the at least one second terminal include at least one of a bonding pad, solder ball pad, redistribution line (RDL) pad, and flip-chip bumping pad.

8. The semiconductor memory module of claim 1, wherein the at least one first terminal and the at least one second terminal are arranged symmetrically to each other to form a pair of semiconductor memory devices having first and second forms, and wherein the at least one first terminal is formed to be of the first form and the at least one second terminal is formed to be of the second form.

9. The semiconductor memory module of claim 1, wherein the at least one first terminal and the at least one second terminal are arranged symmetrically to each other to form a pair of semiconductor memory devices having first and second forms, wherein the at least one first terminal and the at least one second terminal are initially formed to have a basic form, and wherein the at least one first terminal is transformed to be of the first form and the at least one second terminal is transformed to be of the second form by switching option or fuse cutting.

10. The semiconductor memory module of claim 1, wherein the at least one first and the at least one second semiconductor memory devices include at least one of a chip, RDL chip, package, and wafer level package.

11. The semiconductor memory module of claim 1, wherein the at least one first and the at least one second semiconductor memory devices include one of a mono device and a stacked device including stacked mono devices.

12. The semiconductor memory module of claim 1, wherein
the at least one first semiconductor memory device includes a plurality of the first semiconductor memory devices arranged in a first row, and
the at least one second semiconductor memory device includes a plurality of the second semiconductor memory devices arranged in a second row, the second row being parallel and corresponding to the first row.

13. A method of arranging terminals in a semiconductor memory module comprising a first semiconductor memory device and a second semiconductor memory device, the method comprising:
arranging at least one first terminal of the first semiconductor memory device in a first edge region of the first semiconductor memory device; and
arranging at least one second terminal of the second semiconductor memory device in a second edge region of the second semiconductor memory device, the first edge region corresponding to an edge region of the first semiconductor memory device nearest to the second semiconductor memory device, the second edge region corresponding to an edge region of the second semiconductor device nearest to the first semiconductor memory device, wherein the at least one first terminal and the at least one second terminal are arranged symmetrically to each other in the first and the second semiconductor memory devices.

14. The method of claim 13, wherein the at least one first terminal and the at least one second terminal receive command signals or address signals from a common trace.

15. The method of claim 13, wherein the at least one first terminal and the at least one second terminal include at least one of a bonding pad, solder ball pad, RDL pad, and flip-chip bumping pad.

16. The method of claim 13, wherein the first and the second semiconductor memory devices include at least one of a chip, RDL chip, package, and wafer level package.

17. The method of claim 13, wherein the first and second semiconductor memory devices include one of a mono device and a stacked device including stacked mono devices.

18. The method of claim 13, further comprising:
forming the at least one first terminal to be of a first form and forming the at least one second terminal to be of a second form, wherein the first semiconductor memory device and the second semiconductor memory device are arranged to form a pair of semiconductor memory devices having the first form and the second form.

19. A method of using a semiconductor memory module including a first semiconductor memory device including at least one first terminal in a first edge region and a second semiconductor memory device including at least one second terminal in a second edge region, the method comprising:
transmitting at least one signal from an external memory controller through a common module tab, a common trace, and a first stub to the at least one first terminal of the first semiconductor memory device; and
transmitting the at least one signal from the external memory controller through the common module tab, the common trace, and a second stub to the at least one second terminal of the second semiconductor memory device.

20. The method of claim 19, wherein the at least one first and the at least one second terminals receive at least one of a command signal and address signal from the common trace.
